(19) United States
(12) Patent Application Publication
(10) Pub. No.: US 2011/0291120 A1
(43) Pub. Date: Dec. 1, 2011

(54) Light Emitting Devices Using Connection Structures And Methods Of Manufacturing The Same

(75) Inventors: Young-jo Tak, Hwaseong-si (KR); Young-soo Park, Yongin-si (KR); Su-hee Chae, Suwon-si (KR); Bok-ki Min, Suwon-si (KR); Jun-youn Kim, Hwaseong-si (KR); Hyun-gi Hong, Suwon-si (KR); Jae-won Lee, Yongin-si (KR); Hyung-su Jeong, Suwon-si (KR)

(73) Assignee: SAMSUNG ELECTRONICS CO., LTD., Suwon-si (KR)

(21) Appl. No.: 13/109,263

(22) Filed: May 17, 2011

(30) Foreign Application Priority Data
Jun. 1, 2010 (KR) 10-2010-0051977

(51) Int. Cl. H01L 27/15; H01L 33/06

(52) U.S. Cl. 257/88; 438/28; 257/E33.012; 257/E27.12

(57) ABSTRACT

Example embodiments of the present invention relate to a light emitting device having a connection structure and a method of manufacturing the light emitting device. The method of manufacturing may include forming a light emitting region and electrode layers on a substrate in which a plurality of cell regions and a bridge for partially connecting the cell regions are disposed, thereby providing a light emitting device that controls stress with relative ease and integrates electrical connections between the cell regions.

### CROSS-REFERENCE TO RELATED APPLICATION

This application claims priority under 35 U.S.C. §119 to Korean Patent Application No. 10-2010-0051977, filed on Jun. 1, 2010 with the Korean Intellectual Property Office, the disclosure of which is incorporated herein in its entirety by reference.

### BACKGROUND

1. Field

The present disclosure relates to light emitting devices, and more particularly to, higher quality light emitting devices capable of facilitating stress control, maximizing a light emitting surface and extraction of light, and uniformly distributing current.

2. Description of the Related Art

Inorganic semiconductor light emitting devices generally have a diode structure in which n and p type semiconductors are stacked on a substrate through an epitaxial process, and generally discharge energy, which is generated by a recombination of electrons and holes that are injected into the devices, in the form of light. Although the inorganic semiconductor light emitting devices may emit light through the diode structure, they also include active layers in order to increase efficiency of an inner quantum between the n and p type semiconductors.

The inorganic semiconductor light emitting devices have horizontal and vertical structures according to positions of electrodes used for semiconductor layers. Epitaxial growth inorganic semiconductor light emitting devices and flip chip inorganic semiconductor light emitting devices may have the horizontal structures. The inorganic semiconductor light emitting devices having the vertical structures use conductive substrates such as SiC, and use a lift-off method of growing non-conductive substrates and transferring the grown non-conductive substrates to conductive substrates.

It has been known that using the inorganic semiconductor light emitting devices having the vertical structures to manufacture higher output and higher efficiency light emitting devices is advisable, in terms of minimized light emitting areas, uniform distribution of current, heat dissipated by driving devices, simple processing, and the like. SiC substrates have a relatively high unit cost and have difficulty in providing large caliber substrates. To solve these problems, it is advisable to use the lift-off method of growing an epitaxial layer by using sapphire or silicon substrates having relatively low unit cost and larger calibers.

To manufacture higher output and higher efficiency vertical light emitting devices, it is necessary to uniformly distribute current, maximize light emitting areas, and effectively discharge heat and stress generated by driving devices. For example, gallium nitride semiconductors may be epitaxially grown in the conventional silicon substrates. When epitaxial layers grown at relatively high temperatures are cooled at a growth stage, since thermal expansion coefficients of the epitaxial layers are greater than those of the conventional silicon substrates, a tensile stress occurs due to a difference in the thermal expansion coefficients, which causes cracking in the epitaxial layers. Thus, stress control is very important to the manufacture of higher efficiency vertical light emitting devices.

### SUMMARY

Example embodiments of the present invention relate to vertical light emitting devices capable of controlling with relative ease the stress that occurs during the manufacturing of light emitting devices and the integrating of electrical connections of cells. Example embodiments of the present invention also relate to methods of manufacturing the vertical light emitting devices. Additional aspects will be set forth in part in the description which follows and, in part, may be apparent from the description, or may be learned by practice of the presented non-limiting embodiments.

According to a non-limiting aspect of the present invention, a light emitting device may include a plurality of cells; barrier regions disposed between the plurality of cells so as to separate the plurality of cells; and connection portions disposed between the plurality of cells so as to partially connect the plurality of cells, wherein the plurality of cells include a light emitting region including an n type cladding layer, an active layer, and a p type cladding layer; a p type electrode layer on the p type cladding layer; an n type electrode layer extending through the p type electrode layer, the p type cladding layer, and the active layer so as to contact the n type cladding layer; and a passivation layer disposed between the n type electrode layer and the p type electrode layer, the p type cladding layer, and the active layer.

The n type electrode layer may be connected to a reflection layer and a conductive substrate.

The conductive substrate may include any one or more materials selected from the group consisting of Au, Ni, Cu, and W.

The conductive substrate may include any one or more materials selected from the group consisting of Si, Ge, and GaAs.

The connection portions may be connected to the p type electrode layer and the n type electrode layer to uniformly distribute current of the light emitting device.

According to another non-limiting aspect of the present invention, a light emitting device may include a conductive substrate including a plurality of cells disposed thereon, the plurality of cells including a light emitting region, a p type electrode layer on the light emitting region, and an n type electrode layer on the p type electrode layer; demarcation regions configured so as to space the plurality of cells into an array; and bridge portions configured to partially connect adjacent cells of the plurality of cells of the array, the bridge portions having a smaller upper surface area than the plurality of cells.

According to another non-limiting aspect of the present invention, a method of manufacturing a light emitting device may include forming a plurality of cell regions, a cell separation region near the plurality of cell regions, and a bridge on an initial substrate, the bridge partially connecting the plurality of cell regions; forming a light emitting region in the plurality of cell regions and the bridge; forming a p type electrode layer and an n type electrode layer on the light emitting region to form an intermediate structure; transferring the intermediate structure onto a conductive substrate; and removing the initial substrate.

The plurality of cell regions may be formed by forming a trench or a mask pattern in the substrate.

The light emitting region may include an n type cladding layer, an active layer, and a p type cladding layer.

The forming of the p type electrode layer and the n type electrode layer on the light emitting region may include forming the p type electrode on the p type cladding layer; forming a contact hole used to expose the n type cladding layer through the p type electrode layer, the p type cladding layer, and the active layer; forming a passivation layer on the surface of the p type electrode and the sidewall of the contact hole; and forming an n type electrode layer contacting the n type cladding layer inside the contact hole.

One or more contact holes may be formed.

The passivation layer may be formed of a silicon oxide or a silicon nitride.

The method may further include forming a p type pad by removing the light emitting region of the plurality of cell regions in which the contact hole is not formed.

The method may further include charging barrier regions between the plurality of cells regions with an insulation material, after forming the p type electrode layer and the n type electrode layer.

The insulation material may include polymide or spin-on-glass (SOG).

The substrate may be removed by using a laser lift-off method, dry etching, chemical wet etching, or chemical polishing.

The method may further include: performing surface texturing on the light emitting region exposed by removing the substrate.

### BRIEF DESCRIPTION OF THE DRAWINGS

The above and/or other aspects of example embodiments may become more apparent and readily appreciated when the following description is taken in conjunction with the accompanying drawings of which:

FIG. 1A(a) is a plan view of a substrate for a light emitting device in which a bridge is formed according to a non-limiting embodiment of the present invention;

FIGS. 1A(b) and 1A(c) are cross-sectional views of the substrate of FIG. 1A(a) taken along lines L-L′ and m-m′, respectively;

FIGS. 1B(a), 1B(b), and 1B(c) are views of a process of growing semiconductor layers, i.e. epitaxial layers, by using an epitaxial process performed on the substrate of FIG. 1A(a) for the light emitting device in which the bridge is formed, according to a non-limiting embodiment of the present invention;

FIGS. 2A(a) and 2B(a) are plan views of a substrate for a light emitting device in which a mask pattern is formed between cell regions and FIGS. 2A(b), 2A(c), 2B(b), and 2B(c) are cross-sectional views of a process of forming epitaxial layers on the substrate, according to another non-limiting embodiment of the present invention;

FIGS. 3(a), 3(b), and 3(c) are views of a process of forming a p type electrode layer on an epitaxial layer, according to a non-limiting embodiment of the present invention;

FIGS. 4(a), 4(b), and 4(c) are views of an etching process used to form a p type electrode layer, according to a non-limiting embodiment of the present invention;

FIGS. 5(a), 5(b), and 5(c) are views of a process of forming a passivation layer by using an insulation material, according to a non-limiting embodiment of the present invention;

FIGS. 6(a), 6(b), and 6(c) are views of a process of forming an n type electrode layer, according to a non-limiting embodiment of the present invention;

FIGS. 7(a), 7(b), and 7(b) are views of a process of transferring an epitaxial layer formed on a substrate, according to a non-limiting embodiment of the present invention;

FIGS. 8(a), 8(b), and 8(c) are views of a process of removing a substrate on which an epitaxial layer is grown, according to a non-limiting embodiment of the present invention; and

FIGS. 9(a), 9(b), and 9(c) are views of a process of forming a p type pad, according to a non-limiting embodiment of the present invention.

### DETAILED DESCRIPTION

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms, “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Reference will now be made in further detail to various non-limiting embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments herein are merely described, by referring to the figures, to explain certain aspects of the present description. In the drawings, the thicknesses of layers and regions may have been exaggerated for clarity.

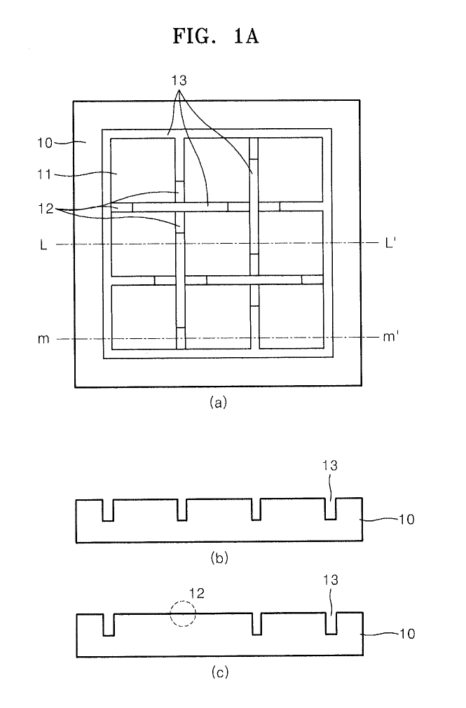

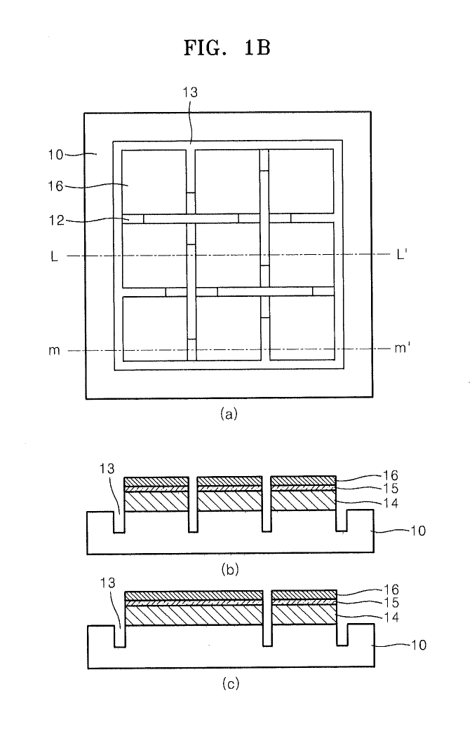

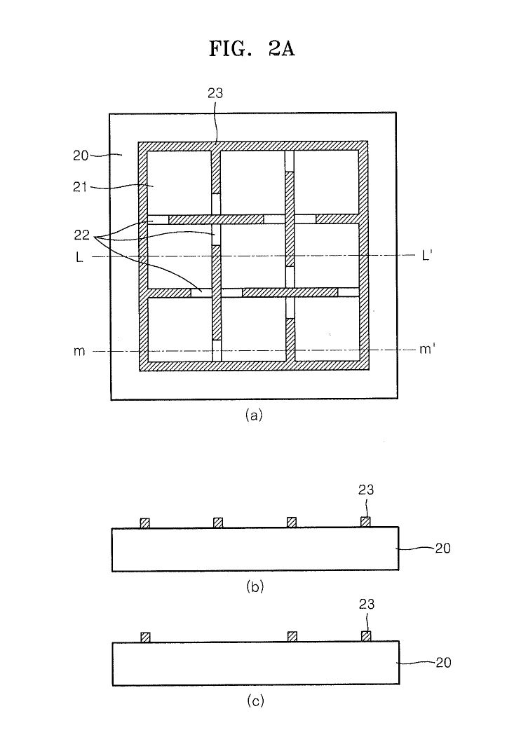

FIG. 1A(a) is a plan view of a substrate 10 for a light emitting device in which a bridge 12 is formed, according to a non-limiting embodiment of the present invention. FIGS. 1A(b) and 1A(c) are cross-sectional views of the substrate 10 taken along lines L-L′ and m-m′, respectively. These views also apply to the other accompanying drawings.

Referring to FIG. 1A(a), a plurality of cell regions 11 are formed in the substrate 10, and a trench 13 that is a cell separation region is formed near each of the cell regions 11. The cell regions 11 are partially connected to each other via the bridge 12.

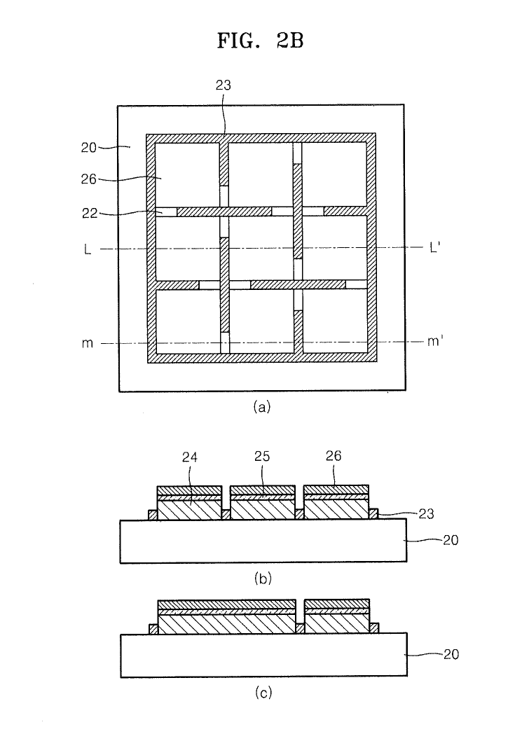

A position and size of each cell region 11 may be defined by using a patterning method before separating epitaxial growth layers of the cell regions 11 and epitaxially growing the epitaxial growth layers. The patterning method is used to etch the substrate 10 and form the trench 13. In addition, the patterning method may be used to selectively etch a mask layer on a substrate and form a cell separation region. This will be described later with reference to FIG. 2A.

When a pattern is formed by etching the substrate 10, an etching process is performed on a region of the substrate 10 excluding the cell regions 11 and the bridge 12 and the trench 13 is formed. In this regard, although the bridge 12 is shown as formed between the cell regions 11 in rectangular array shapes, the cell regions 11 viewed on a plane may have various shapes, such as circular shapes, polygonal shapes, etc. The smaller the sizes of the cell regions 11, the more it is possible to prevent a crack from occurring in epitaxial layers when a semiconductor layer is epitaxially grown on upper portions of the cell regions 11. However, when the sizes of the cell regions 11 are too small, a light emitting area is reduced, causing a reduction in the light emitting efficiency. Thus, the cell regions 11 may have appropriate sizes between about 10˜2000 μm. The bridge 12 is used to connect the cell regions 11, and is not limited in terms of size. The shape, size, and position of the bridge 12 may be determined according to the sizes, shapes, and arrangements of the cell regions 11. For example, if the bridge 12 has a relatively large size, then a region where the epitaxial growth layer and the substrate 10 contact each other increases, which may not prevent a crack from occurring in the epitaxial layers. Thus, the size and position of the bridge 12 may be determined in such a way that overall stress may be reduced.

Although there may be no step and boundary between the cell regions 11 and the bridge 12, the cell regions 11 and the bridge 12 are distinguished from each other by solid lines in FIG. 1A(a). This also applies to the other drawings. Alternatively, it should be understood that a differentiating structure may be provided so as to physically distinguish between the cell regions 11 and the bridge 12.

Referring to FIG. 1A(b), the trench 13 is formed between the substrate 10 and the cell regions 11. Referring to FIG. 1A(c), the bridge 12 is for connecting the cell regions 11.

FIGS. 1B(a), 1B(b), and 1B(c) are views of a process of growing semiconductor layers, i.e. epitaxial layers, by using an epitaxial process performed on the substrate 10 for the light emitting device in which the bridge 12 is formed, according to a non-limiting embodiment of the present invention.

Referring to FIGS. 1B(a), 1B(b), and 1B(c), a light emitting region may be formed by sequentially growing the epitaxial layers, such as an n type cladding layer 14, an active layer 15, and a p type cladding layer 16, on the cell regions 11 and the bridge 12. It should be understood that the n type cladding layer 14, the active layer 15, and the p type cladding layer 16 may be formed of various materials suitable for use in light emitting devices and, thus, not limited to any of the examples discussed herein. Although not shown, a buffer layer may be further formed between the substrate 10 and the n type cladding layer 14. When the epitaxial layers are cooled by controlling a contact area between the substrate 10 and the epitaxial layers and growing the epitaxial layers, or the substrate 10 is removed, stress is reduced, thereby preventing a crack from occurring in the epitaxial layers. The epitaxial layers grown on the substrate 10 are formed on the cell regions 11 and the bridge 12 according to the shape of a pattern formed on the substrate 10. A material layer formed on the bridge 12 may be the same as that formed on the cell regions 11, and both material layers may be referred to as connection layers.

FIGS. 2A(a) and 2B(a) are plan views of a substrate 20 for a light emitting device in which a mask pattern 23 is formed between cell regions 21 and FIGS. 2A(b), 2A(c), 2B(b), and 2B(c) are cross-sectional views of a process of forming epitaxial layers on the substrate 20, according to another non-limiting embodiment of the present invention.

Referring to FIG. 2A(a), the cell regions 21 are formed on the substrate 20, and the mask pattern 23 that is a cell separation region is formed around the cell regions 21. The cell regions 21 are connected to each other via a bridge 22.

The mask pattern 23 may be formed by forming a mask layer formed of Si oxide or Si nitride on the substrate 20 and selectively etching the mask layer. Referring to FIGS. 2A(b) and 2A(c), the mask pattern 23 is formed in the cell regions 21 on the substrate 20 excluding the bridge 22. The cell regions 21 may have various shapes such as rectangular shapes, circular shapes, polygonal shapes, etc. The sizes of the cell regions 21 may be appropriately determined between about 10˜2000 μm. The bridge 22 is used to connect the cell regions 21, and is not limited to its size.

FIGS. 2B(a), 2B(b), and 2B(c) are views of a process of growing semiconductor layers, i.e. epitaxial layers, by using an epitaxial process performed on the substrate 20 of FIG. 2A(a) for the light emitting device.

Referring to FIGS. 2B(a), 2B(b), and 2B(c), a light emitting region may be formed by sequentially growing the epitaxial layers, such as an n type cladding layer 24, an active layer 25, and a p type cladding layer 26, on the cell regions 21 and the bridge 22. It should be understood that the n type cladding layer 24, the active layer 25, and the p type cladding layer 26 may be formed of various materials suitable for use in light emitting devices and, thus, are not limited to the examples discussed herein. Although not shown, a buffer layer may be further formed between the substrate 20 and the n cladding layer 24.

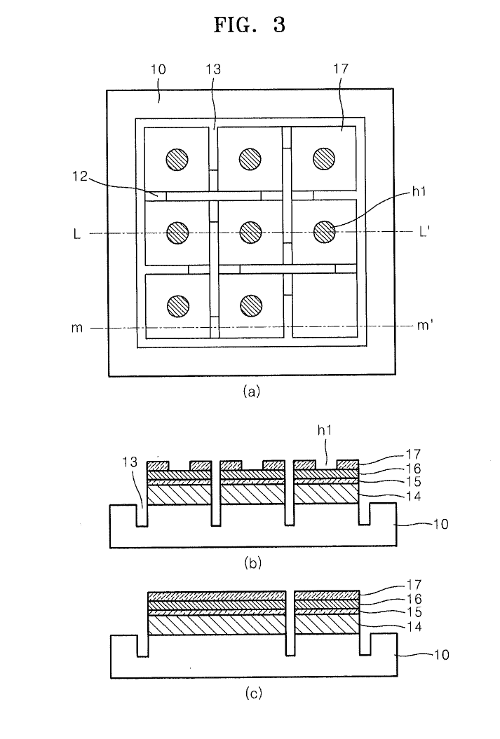

As shown in FIGS. 1A(a) through 2A(c), the trench 13 or the mask pattern 23 may be formed to define the cell regions 11 and 21 and the bridges 12 and 22. As shown in FIGS. 1B(a) through 2B(c), the epitaxial layers may be formed on the substrates for the light emitting devices. A subsequent process of forming an electrode may be the same for substrates 10 and 20. For purposes of brevity, the subsequent process will just be discussed with reference to substrate 10. The subsequent process that is to be performed on the substrate 10 for the light emitting device in which the trench 13 of FIG. 1A(b) is formed will now be described with reference to FIGS. 3 through 9.

FIGS. 3(a), 3(b), and 3(c) are views of a process of forming a p type electrode layer 17 on an epitaxial layer, according to a non-limiting embodiment of the present invention. Referring to FIGS. 3(a), 3(b), and 3(c), the p type electrode layer 17 is formed by coating a metal or a conductive material, such as a conductive metal oxide, on a p type cladding layer 16. In this regard, a part of the p type cladding layer 16 is exposed to form an n type electrode. The p type electrode layer 17 may be formed on the bridge 12 and be electrically connected to all cell regions. A p type electrode contact will be formed in the p type electrode layer 17 in which a hole h1 is not formed in the cell regions after performing wafer bonding.

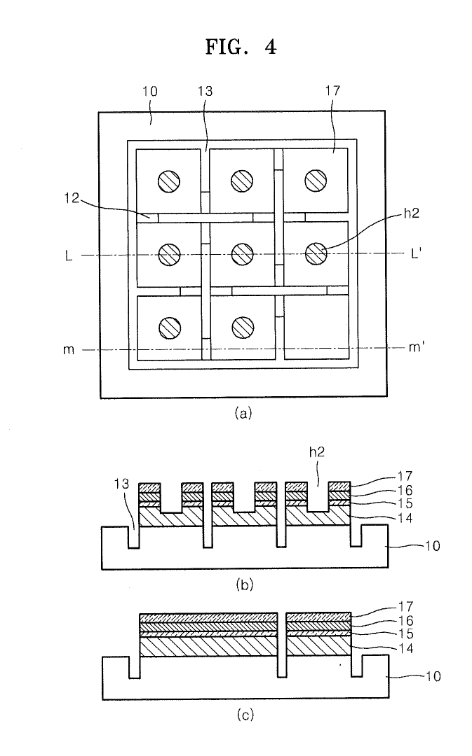

FIGS. 4(a), 4(b), and 4(c) are views of an etching process used to form an n type electrode layer, according to a non-limiting embodiment of the present invention. Referring to FIGS. 4(a), 4(b), and 4(c), a contact hole h2 is formed by etching an epitaxial layer through the hole h1 of FIGS. 3(a), 3(b), and 3(c) in which the p type electrode layer 17 is not formed. In this regard, the epitaxial layer is etched until a part of the n type cladding layer 14 is exposed. A dry etching processing may be used for the epitaxial layer by using the p type electrode layer 17 as an etching mask. To prevent the p type electrode layer 17 from being damaged, an etching mask, such as a silicon oxide, may be selectively formed on the p type electrode layer 17 during the process of forming the p type electrode layer 17 of FIGS. 3(a), 3(b), and 3(c).

The size, number, and arrangement of p type electrodes may be optimally determined through a simulation in terms of a uniform distribution of current in a unit cell. Although one contact hole h2 is formed in each cell so as to form the p type electrode layer 17 in FIGS. 4(a), 4(b), and 4(c), a p type electrode material may be coated in a subsequent process by selectively forming a plurality of contact holes h2 in each cell.

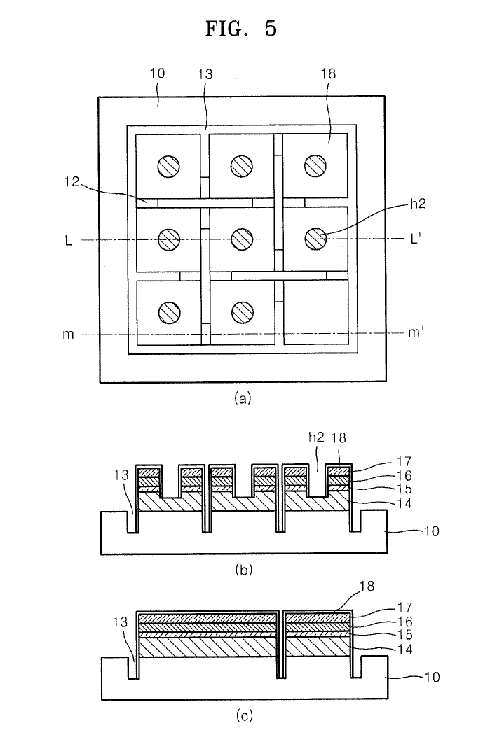

FIGS. 5(a), 5(b), and 5(c) are views of a process of forming a passivation layer 18 by using an insulation material, according to a non-limiting embodiment of the present invention. Referring to FIGS. 5(a), 5(b), and 5(c), the passivation layer 18 is formed on the surface of the p type electrode layer 17, the side surface of an epitaxial layer, and the side portions of the contact holes h2. The passivation layer 18 is formed to electrically separate the p type electrode layer 17 and an n type electrode layer that will be formed. The surface of the n type cladding layer 14 inside the contact hole h2 in which an n type electrode contact will be formed is exposed through a photo process. The passivation layer 18 may be formed by stacking a silicon oxide and/or a silicon nitride by performing plasma enhanced chemical vapour deposition (PECVD) in the side surface of the epitaxial layer, although example embodiments are not limited thereto.

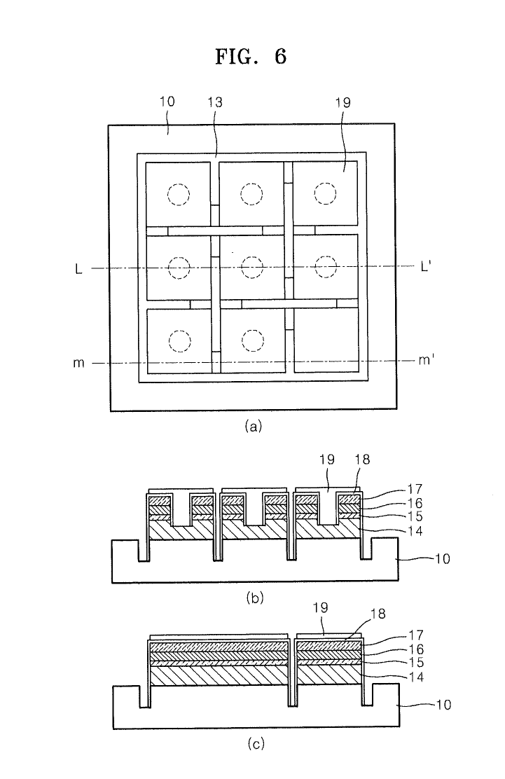

FIGS. 6(a), 6(b), and 6(c) are views of a process of forming an n type electrode layer 19, according to a non-limiting embodiment of the present invention. Referring to FIGS. 6(a), 6(b), and 6(c), the n type electrode layer 19 is formed by coating a metal or a conductive metal oxide over the contact hole h2 and on the passivation layer 18 of FIGS. 5(a), 5(b), and 5(c). In this regard, an n type conductive material may be wholly or partially filled in the contact hole h2 (e.g., in the form of a plug), and may have a planarization surface of a sufficient size in terms of a wafer bonding process that will be performed.

As described above, although the n type electrode layer 19 is discussed as being formed after the p type electrode layer 17 is formed with reference to FIGS. 3(a) through 6(c), it should be understood that, alternatively, the p type electrode layer 17 may be formed after the n type electrode layer 19 is formed.

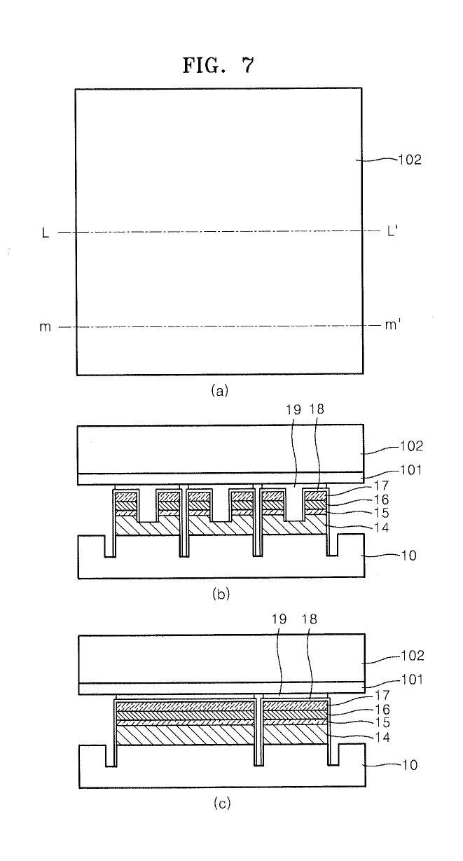

FIGS. 7(a), 7(b), and 7(c) are views of a process of transferring an epitaxial layer formed on a substrate, according to a non-limiting embodiment of the present invention. Referring to FIGS. 7(a), 7(b), and 7(c), a conductive substrate 102 is attached onto the n type electrode layer 19. The conductive substrate 102 may be a metal substrate, and may be formed of, for example, any one or more of the elements selected from the group consisting of, Au, Ni, Cu, and W. The conductive substrate 102 may also be formed of a semiconductor material, for example, Si, Ge, or GaAs. The epitaxial layer may be transferred by using a plating method or a substrate bonding method. A reflection layer 101 may be further formed between the n type electrode layer 19 and the conductive substrate 102. The reflection layer 101 may be formed of a metal material capable of reflecting a light generated in an active layer. A suitable metal material may include, for example, Ti, Ag, Al, or Pt, although example embodiments are not limited thereto.

Before transferring the epitaxial layer, barrier regions between cells may be charged with an insulation material, for example, a polymide material or a spin-on-glass (SOG) material. Although the barrier regions between cells may be charged with the insulation material, alternatively, the barrier regions between cells may be charged with air that contains no material.

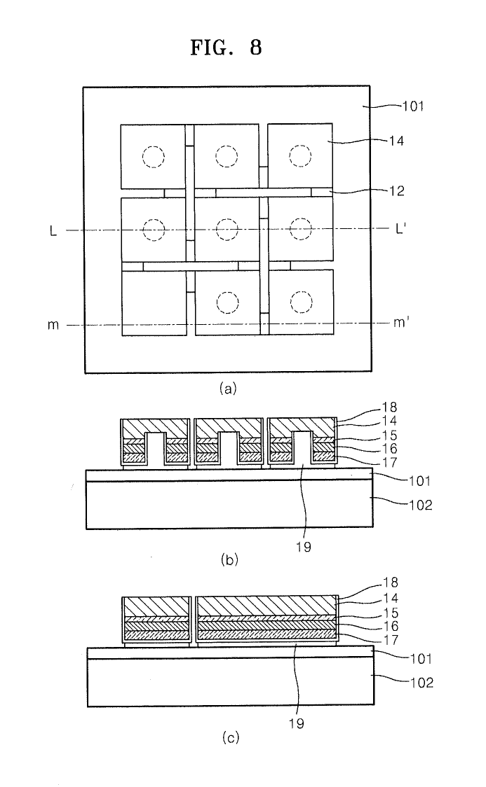

FIGS. 8(a), 8(b), and 8(c) are views of a process of removing a substrate 10 on which an epitaxial layer is grown, according to a non-limiting embodiment of the present invention. Referring to FIGS. 8(a), 8(b), and 8(c), the process of removing the substrate 10 may be selectively determined according to a type of the substrate 10. For example, a laser lift-off method may be used to remove a sapphire substrate, and dry etching, chemical wet etching, or chemical polishing may be used to remove a silicon substrate. In order to more efficiently extract light generated in the active layer 15, surface texturing may be performed on a buffer layer or the n type cladding layer 14 that is exposed after the substrate 10 is removed.

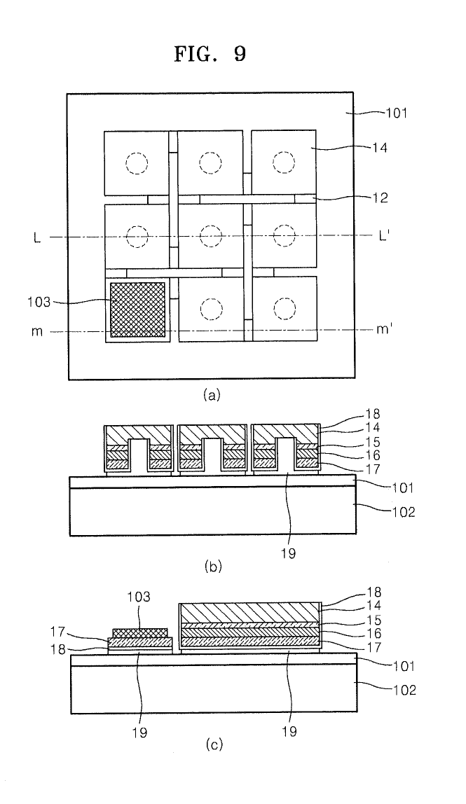

FIGS. 9(a), 9(b), and 9(c) are views of a process of forming a p type pad 103, according to a non-limiting embodiment of the present invention. Referring to FIGS. 9(a), 9(b), and 9(c), after an upper portion of a part of cells in which an n type electrode contact hole is not formed in an array structure, for example, a light emitting region, is etched, the p type pad 103 is formed on an upper portion of a part of the etched cells. The p type pad 103 is formed on the p type electrode layer 17. Power may be supplied to the p type electrode layer 17 through the p type pad 103, and to the n type electrode layer 19 through the conductive substrate 102. Power may be supplied between the cells through connection layers.

As described above, each cell of the light emitting device of the present embodiment may include a light emitting region including the n type cladding layer 14, the active layer 15, and the p type cladding layer 16. The p type electrode layer 17 may be formed on the p type cladding layer 16 of the light emitting region. The n type electrode layer 19 may be formed in the contact hole h2 by which the n type cladding layer 14 is exposed through the p type electrode layer 17 and the light emitting region. The passivation layer 18 may be formed between the p type electrode layer 17 and the n type electrode layer 19. Barrier portions that separate a plurality of cells may be formed between the cells. Connection portions may be formed in a bridge via which the cells are partially connected to each other. The connection portions may be connected to the p type electrode layer 17 and the n type electrode layer 19 to uniformly distribute current of the light emitting device.

As a result, in the light emitting device of the present embodiment, all regions of the p type cladding layer 16 are electrically connected to each other through the p type pad 103, and the inner regions of the n type cladding layer 14 may be electrically connected to each other through the conductive substrate 102.

As described above, the non-limiting embodiments of the present invention provide a light emitting device that controls stress with relative ease during epitaxial growth or removal of an epitaxial substrate by arranging cells having relatively small areas in an array shape and integrating electrical connections between the cells by connecting the cells via a bridge. The non-limiting embodiments of the present invention also provide a light emitting device that maximizes a light emitting area by controlling an electrode formation region and uniformly distributes current.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims. The descriptions of features or aspects of each embodiment should typically be considered as available for other similar features or aspects of other embodiments.

What is claimed is:

1. A light emitting device comprising:
a plurality of cells;
barrier regions disposed between the plurality of cells so as to separate the plurality of cells; and
connection portions disposed between the plurality of cells so as to partially connect the plurality of cells,
wherein the plurality of cells include
a light emitting region including an n type cladding layer, an active layer, and a p type cladding layer;
a p type electrode layer on the p type cladding layer;
an n type electrode layer extending through the p type electrode layer, the p type cladding layer, and the active layer so as to contact the n type cladding layer; and
a passivation layer disposed between the n type electrode layer and the p type electrode layer, the p type cladding layer, and the active layer.

2. The light emitting device of claim 1, further comprising:
a reflection layer and a conductive substrate connected to the n type electrode layer.

3. The light emitting device of claim 2, wherein the conductive substrate comprises one or more materials selected from the group consisting of Au, Ni, Cu, and W.

4. The light emitting device of claim 2, wherein the conductive substrate comprises one or more materials selected from the group consisting of Si, Ge, and GaAs.

5. The light emitting device of claim 1, wherein the connection portions are connected to the p type electrode layer and the n type electrode layer so as to uniformly distribute a current of the light emitting device.

6. A method of manufacturing a light emitting device, the method comprising:
forming a plurality of cell regions, a cell separation region near the plurality of cell regions, and a bridge on an initial substrate, the bridge partially connecting the plurality of cell regions;
forming a light emitting region in the plurality of cell regions and the bridge;
forming a p type electrode layer and an n type electrode layer on the light emitting region to form an intermediate structure;
transferring the intermediate structure onto a conductive substrate; and
removing the initial substrate.

7. The method of claim 6, wherein the forming a plurality of cell regions includes forming a trench or a mask pattern in the initial substrate.

8. The method of claim 6, wherein the forming a light emitting region includes forming an n type cladding layer, an active layer, and a p type cladding layer.

9. The method of claim 8, wherein the forming a p type electrode layer and an n type electrode layer on the light emitting region comprises:
forming the p type electrode on the p type cladding layer;
forming a contact hole through the p type electrode layer, the p type cladding layer, and the active layer so as to expose the n type cladding layer;
forming a passivation layer on a surface of the p type electrode and a sidewall of the contact hole; and
forming the n type electrode layer in the contact hole so as to contact the n type cladding layer.

10. The method of claim 9, wherein the forming a contact hole includes forming one or more contact holes.

11. The method of claim 9, wherein the passivation layer is formed of a silicon oxide or a silicon nitride.

12. The method of claim 9, further comprising:
removing the light emitting region from the plurality of cell regions in which the contact hole was not formed; and
forming a p type pad in one or more of the plurality of cell regions where the light emitting region was removed.

13. The method of claim 6, further comprising:
forming barrier regions between the plurality of cells regions with an insulation material, after forming the p type electrode layer and the n type electrode layer.

14. The method of claim 13, wherein the insulation material includes a polymide or spin-on-glass (SOG).

15. The method of claim 6, wherein removing the initial substrate involves a laser lift-off method, dry etching, chemical wet etching, or chemical polishing.

16. The method of claim 6, further comprising:
performing surface texturing on the light emitting region exposed by the removing of the initial substrate.

17. A light emitting device comprising:
a conductive substrate including a plurality of cells disposed thereon, the plurality of cells including a light emitting region, a p type electrode layer on the light emitting region, and an n type electrode layer on the p type electrode layer;
demarcation regions configured so as to space the plurality of cells into an array; and
bridge portions configured to partially connect adjacent cells of the plurality of cells of the array, the bridge portions having a smaller upper surface area than the plurality of cells.

18. The light emitting device of claim 17, wherein the light emitting region includes an n type cladding layer, an active layer on the n type cladding layer, and a p type cladding layer on the active layer.

19. The light emitting device of claim 18, wherein the n type electrode layer extends through the p type electrode layer, the p type cladding layer, and the active layer so as to contact the n type cladding layer.

20. The light emitting device of claim 17, further comprising:
a p type pad in one or more of the plurality of cell regions that do not have the light emitting region.
